(19) United States
(12) Patent Application Publication
(10) Pub. No.: US 2026/0129903 A1
(43) Pub. Date: May 7, 2026

(54) SEMICONDUCTOR DEVICE

(71) Applicant: FUJI ELECTRIC CO., LTD., Kawasaki-shi (JP)

(72) Inventor: Chansoon KOO, Matsumoto-city (JP)

(73) Assignee: FUJI ELECTRIC CO., LTD., Kawasaki-shi (JP)

(21) Appl. No.: 19/437,940

(22) Filed: Dec. 31, 2025

Related U.S. Application Data
(63) Continuation of application No. PCT/JP2024/041892, filed on Nov. 26, 2024.

(30) Foreign Application Priority Data
Jan. 10, 2024 (JP) 2024-002082

(51) Int. Cl. H10D 30/66; H10D 62/10; H10D 62/60; H10D 62/832

(52) U.S. Cl. CPC H10D 30/665; H10D 30/668; H10D 62/102; H10D 62/124; H10D 62/60; H10D 62/8325

(57) ABSTRACT

A semiconductor device, including: a semiconductor substrate having an active region and a termination region; a first semiconductor layer provided on the semiconductor substrate in the active region and the termination region; a plurality of first semiconductor regions provided in the first semiconductor layer in the active region; a second semiconductor region provided in the termination region, and having a plurality of first sub-regions provided at intervals; a third semiconductor region provided in the first semiconductor layer in the termination region, between a predetermined number of the plurality of first sub-regions from an end of the first semiconductor regions; and a plurality of fourth semiconductor regions provided in the first semiconductor layer in the termination region, between the first semiconductor layer and the third semiconductor region. The predetermined number of the first sub-regions are connected by the third semiconductor region and the plurality of fourth semiconductor regions.

### CROSS REFERENCE TO RELATED APPLICATIONS

This is a continuation application of International Application PCT/JP2024/041892 filed on Nov. 26, 2024 which claims priority from a Japanese Patent Application No. 2024-002082 filed on Jan. 10, 2024, the contents of which are incorporated herein by reference.

### BACKGROUND OF THE INVENTION

### 1. Field of the Invention

Embodiments of the disclosure relate to a semiconductor device.

### 2. Description of the Related Art

Conventionally, a semiconductor device has been proposed in which in an edge termination portion, a P layer (field limiting ring (FLR)) is provided at a constant pitch and a P-layer is provided so as to connect the P layer, the P-layer having a dopant concentration lower than that of the P layer and a depth smaller than that of the P layer, whereby leakage current may be reduced (for example, refer to Japanese Laid-Open Patent Publication No. 2020-198375).

### SUMMARY OF THE INVENTION

According to an embodiment of the present disclosure, a semiconductor device, includes: a semiconductor substrate of a first conductivity type, having an active region through which a main current flows and a termination region surrounding a periphery of the active region, in a plan view; a first semiconductor layer of the first conductivity type, provided on the semiconductor substrate in the active region and the termination region, the first semiconductor layer having a dopant concentration lower than a dopant concentration of the semiconductor substrate, the first semiconductor layer having a first surface and a second surface opposite to each other, the second surface facing the semiconductor substrate; a plurality of first semiconductor regions of a second conductivity type, provided in the first semiconductor layer, at the first surface thereof in the active region; a second semiconductor region of the second conductivity type, provided in the termination region, the second semiconductor region having a plurality of first sub-regions of the second conductivity type, provided at intervals at the first surface of the first semiconductor layer, each of the plurality of first sub-regions having a first surface and a second surface opposite of each other, the second surface facing the semiconductor substrate; a third semiconductor region of the second conductivity type, provided in the first semiconductor layer in the termination region, between a predetermined number of the plurality of first sub-regions from an end of the plurality of first semiconductor regions, the third semiconductor region having a concentration lower than that of the plurality of first sub-regions, the third semiconductor region having a first surface and a second surface opposite to each other, the second surface facing the semiconductor substrate and being provided closer to the first surface of the first semiconductor layer than is the first surface of each of the plurality of first sub-regions; and a plurality of fourth semiconductor regions of the first conductivity type, provided in the first semiconductor layer in the termination region, between the first surface of the first semiconductor layer and the third semiconductor region. The predetermined number of the plurality of first sub-regions are connected by the third semiconductor region and the plurality of fourth semiconductor regions.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a silicon carbide semiconductor device according to an embodiment, from an edge termination region to an active region.

FIG. 2 is a cross-sectional view depicting the structure of the active region of the silicon carbide semiconductor device according to the embodiment.

FIG. 3 is a graph depicting concentration distribution in a depth direction of a p-type layer of the silicon carbide semiconductor device according to the embodiment.

FIG. 4 is a graph depicting change of edge breakdown voltage due to edge surface charge and variation of FLR dimensions of a conventional silicon carbide semiconductor device.

FIG. 5 is a graph depicting change of edge breakdown voltage due to edge surface charge and variation of FLR dimensions of the silicon carbide semiconductor device according to the embodiment.

FIG. 6 is a cross-sectional view depicting electric field distribution of the conventional silicon carbide semiconductor device.

FIG. 7 is a graph depicting the electric field distribution of the conventional silicon carbide semiconductor device.

FIG. 8 is a cross-sectional view depicting location of dielectric breakdown of the conventional silicon carbide semiconductor device.

FIG. 9 is a cross-sectional view depicting electric field distribution of the silicon carbide semiconductor device according to the embodiment.

FIG. 10 is a graph depicting the electric field distribution of the silicon carbide semiconductor device according to the embodiment.

FIG. 11 is a cross-sectional view depicting location of dielectric breakdown of the silicon carbide semiconductor device according to the embodiment.

FIG. 12 is a graph depicting the electric field distribution of the conventional silicon carbide semiconductor device and the silicon carbide semiconductor device according to the embodiment.

### DETAILED DESCRIPTION OF THE INVENTION

First, problems associated with the conventional techniques are discussed. In a conventional field limiting ring (FLR) structure, a problem arises in that variation of breakdown voltage is large due to variations in dimensions and edge surface charge.

An overview of the present disclosure is described. A semiconductor device according to the present disclosure solving the problems above and achieving an object has the following features. The semiconductor device has a semiconductor substrate of a first conductivity type, the semiconductor substrate having an active region through which a main current flows and a termination region surrounding a periphery of the active region, in a plan view. In the active region, in the semiconductor substrate, at a front surface thereof, a first semiconductor layer of the first conductivity type and having a dopant concentration lower than that of the semiconductor substrate is provided and a first semiconductor region of a second conductivity type is provided at a first surface of the first semiconductor layer, opposite to a second surface thereof facing the semiconductor substrate. Provided in the termination region are: the first semiconductor layer; a second semiconductor region of the second conductivity type, the second semiconductor region having a plurality of first sub-regions of the second conductivity type, provided at intervals at the first surface of the first semiconductor layer, each of the plurality of first sub-regions having a first surface and a second surface opposite of each other, the second surface facing the semiconductor substrate; a third semiconductor region of the second conductivity type, provided in the first semiconductor layer in the termination region, between a predetermined number of the plurality of first sub-regions from an end of the first semiconductor region, the third semiconductor region having a concentration lower than that of the plurality of first sub-regions, the third semiconductor region having a first surface and a second surface opposite to each other, the second surface facing the semiconductor substrate and being provided closer to the first surface of the first semiconductor layer than is the first surface of each of the plurality of first sub-regions; and a plurality of fourth semiconductor regions of the first conductivity type, provided in the first semiconductor layer in the termination region, between the first surface of the first semiconductor layer and the third semiconductor region. The plurality of first sub-regions are connected by the third semiconductor region and the plurality of fourth semiconductor regions.

According to the disclosure above, the low-concentration inter-FLR layer (third semiconductor region of the second conductivity type) is provided in a form that connects gaps between FLRs (first sub-regions of the second conductivity type), whereby sufficient surface charge tolerance is ensured even when dimensions of each of the FLRs of the FLR structure vary, thereby enabling stabilization of the edge breakdown voltage. Furthermore, the breakdown voltage may be stably ensured even without performing SiC etching and high-acceleration ion implantation of the edge termination region, and since neither SiC etching nor high-acceleration ion implantation is used, manufacturing costs may be reduced.

Further, in the semiconductor device according to the present disclosure, in the disclosure above, each of the plurality of first sub-regions has a center region having a second sub-region with a relatively high dopant concentration at the first surface of the first semiconductor layer and a third sub-region with a relatively lower dopant concentration at a side of the second sub-region facing the semiconductor substrate, an inner-side region provided closer to the active region than is the center region, and an outer-side region provided opposite to the inner-side region with the center region intervening therebetween, and the inner-side region and the outer-side region have a dopant concentration that is lower than that of the second sub-region.

Further, in the semiconductor device according to the present disclosure, in the disclosure above, the plurality of fourth semiconductor regions is provided from the first surface of the first semiconductor layer to the first surface of the third semiconductor region, and each of the plurality of fourth semiconductor regions has a thickness not more than a distance from the second surface of the third semiconductor region to the second surface of the each of the plurality of first sub-regions.

Further, in the semiconductor device according to the present disclosure, in the disclosure above, the plurality of fourth semiconductor regions is provided from the first surface of the first semiconductor layer to the first surface of the third semiconductor region, and each of the plurality of fourth semiconductor regions has a thickness that is less than a thickness of the second sub-region of the each of the plurality of first sub-regions.

Further, in the semiconductor device according to the present disclosure, in the disclosure above, in the each of the plurality of first sub-regions: the dopant concentration of the second sub-region is in a range of 5×10¹⁹ cm⁻³ to 2×10²⁰ cm⁻, the dopant concentration of the third sub-region of the center region is in a range of 1×10¹⁶ cm⁻³ to 5×10¹⁹ cm⁻³, the dopant concentration of the inner-side region and outer-side region is in a range of 1×10¹⁶ cm⁻³ to 5×10¹⁹ cm⁻.

Further, in the semiconductor device according to the present disclosure, in the disclosure above, in the each of the plurality of first sub-regions, in a direction parallel to the first surface of the first semiconductor layer, a width of the center region is wider than a width of the inner-side region and a width of the outer-side region.

Further, in the semiconductor device according to the present disclosure, in the disclosure above, in the each of the plurality of first sub-regions, a width of the inner-side region and a width of the outer-side region are in a range of 3% to 20% of a width of an innermost one of the plurality of first sub-regions provided closest to the active region.

Further, in the semiconductor device according to the present disclosure, in the disclosure above, the first surface of the first semiconductor region and the first surface of the second semiconductor region are a same as the first surface of the first semiconductor layer.

Further, in the semiconductor device according to the present disclosure, in the disclosure above, the plurality of first sub-regions has a plurality of widths and is disposed in descending order of the widths in a direction from the active region to the termination region, at different intervals each being larger than an adjacent one closer to the active region, the plurality of first sub-regions includes an innermost one that is closest to the active region and has a width of 6.0 μm or greater at the first surface of the first semiconductor layer and an outermost one that is farthest from the active region and has a width of 2.0 μm at the first surface of the first semiconductor layer, the width of the each of the plurality of first sub-regions is equal to or less than the width of an adjacent one of the plurality of first sub-regions closer to the active region, at the first surface of the first semiconductor layer, the intervals between the plurality of first sub-regions includes an innermost interval that is 2.0 μm or less and closest to the active region and an outermost interval that is 3.0 μm or less and farthest from the active region, any one of the intervals between the plurality of first sub-regions is greater than an adjacent one of the intervals closer to the active region, and the plurality of first sub-regions includes ten or more first sub-regions.

Further, in the semiconductor device according to the present disclosure, in the disclosure above, a dopant concentration of the third semiconductor region exhibits a maximum value closer to the semiconductor substrate than to the first surface of the first semiconductor layer, the maximum value being 2×10¹⁷ cm⁻³ or less and higher than the dopant concentration of the first semiconductor layer, and the dopant concentration of the third semiconductor region, in a region deeper than a depth where a dopant concentration of the plurality of first sub-regions exhibits a maximum value, is lower than the dopant concentration of the plurality of first sub-regions.

Further, in the semiconductor device according to the present disclosure, in the disclosure above, the third semiconductor region has a first end and a second end opposite to each other, the first end facing the active region, and the second end being farther from the active region than is a portion where a first one of the intervals from the active region is 1.5 μm or more or a width of any one of the plurality of first sub-regions is 3.0 μm or less.

Findings underlying the present disclosure are discussed. First, problems associated with conventional semiconductor devices are discussed. In a semiconductor device, an edge termination region that has a voltage withstanding structure and surrounds the periphery of an active region through which current flows during an on-state is provided. In a power semiconductor device, the voltage withstanding structure is fabricated by forming a p-type structure at a surface of an n-type substrate. In a semiconductor device containing silicon carbide (SiC) as a semiconductor material (hereinafter, silicon carbide semiconductor device), main structures used are spatially modulated junction termination extension (JTE) structures, FLR structures, or a combination of thereof.

The voltage withstanding structure of the edge termination region plays a role in relaxing electric field concentration at an end of the active region and thereby making the edge breakdown voltage not less than that of the active region. As a result, in the active region, which has a larger area than that of the edge termination region, a risk of thermal breakdown of the chip is reduced by causing dielectric breakdown, and the effect of charge accumulation at the surface of the edge termination region is also reduced thereby stabilizing the breakdown voltage.

In a space-modulated JTE structure, a patterned p-type region (JTE) forms a structural concentration distribution, whereby electric field concentration is prevented. In a FLR structure, p-type regions are disposed in a ring shape when viewed from the surface, whereby the electric field is distributed and a high breakdown voltage is obtained. Furthermore, a structure is conceivable in which a FLR is disposed relatively close to the active region and a JTE is combined so as to cover the FLR.

While a space-modulated JTE structure may reduce the effects of variation of dimensions and surface change of the edge termination region, a formation process of the active region and additional multiple ion-implantations are necessary and thus, manufacturing cost is high. Further, in SiC in which diffusion of a dopant is difficult, to ensure a same depth as that of the active region, etching of surface SiC or ion-implantation with high acceleration energy is necessary, which also increases manufacturing cost. Further, in a FLR structure, while ion-implantation is completed in one session and collective formation thereof with the p-type regions of the active region is possible, whereby the manufacturing cost is relatively low, fluctuation of the breakdown voltage due to variations in dimensions and edge surface charge is large. In a structure combining the FLR formed concurrently with the active region and the JTE, while ion-implantation is suppressed to a single session and the breakdown voltage may be stabilized, the high cost necessary to ensure the depth remains a problem.

As described, with the conventional voltage withstanding structures, manufacturing cost and fluctuation of the breakdown voltage cannot both be addressed. With the present disclosure, a semiconductor device is provided in which a FLR structure is adopted, ion-implantation is completed by a single session and collective formation thereof with the p-type regions of the active region is possible, whereby manufacturing cost is relatively low and furthermore, fluctuation of the breakdown voltage due to variations in dimensions and edge surface charge is reduced.

Embodiments of a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. Cases where symbols such as n's and p's that include + or − are the same indicate that concentrations are close and therefore, the concentrations are not necessarily equal. In the description of the embodiments below and the accompanying drawings, main portions that are identical will be given the same reference numerals and will not be repeatedly described. Further, with consideration of variation in manufacturing, description indicating the same or equal may be within 5%.

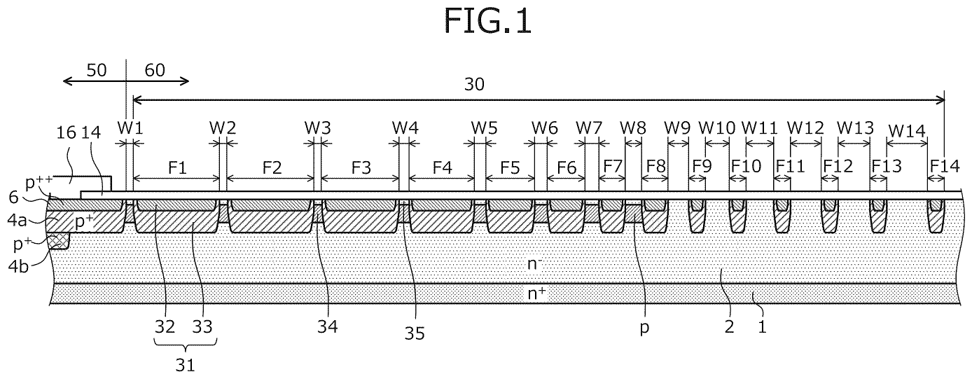

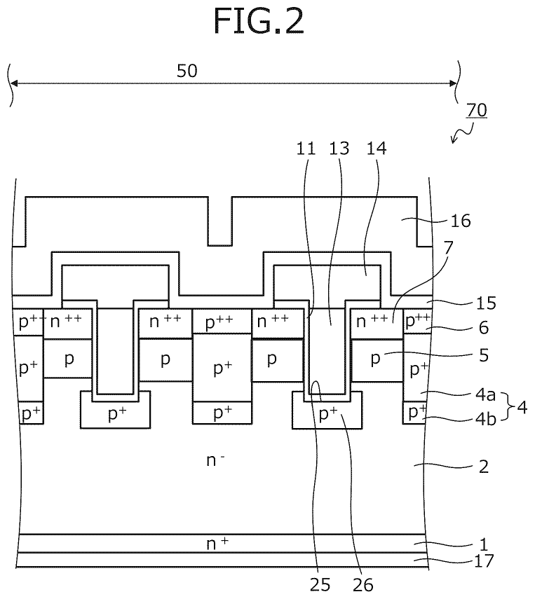

A semiconductor device according to the present disclosure contains a wide band gap semiconductor. In the embodiment, a metal oxide semiconductor field effect transistor (MOSFET) is described as an example of a silicon carbide semiconductor device fabricated using, for example, silicon carbide (SiC) as a wide band gap semiconductor. FIG. 1 is a cross-sectional view depicting a structure of the silicon carbide semiconductor device according to the embodiment, from an edge termination region to an active region. FIG. 2 is a cross-sectional view depicting the structure of the active region of the silicon carbide semiconductor device according to the embodiment.

As depicted in FIGS. 1 and 2, a silicon carbide semiconductor device 70 according to the embodiment includes a semiconductor substrate (hereinafter, silicon carbide substrate (semiconductor substrate (semiconductor chip))) containing silicon carbide and having an active region 50 and an edge termination region 60 surrounding a periphery of the active region 50, in a plan view. The active region 50 is a region through which current flows during an on-state. The edge termination region 60 is a region that relaxes electric field of a front side of a drift region of the substrate and that maintains the breakdown voltage.

The silicon carbide substrate has an n⁺-type starting substrate (n⁺-type silicon carbide substrate, semiconductor substrate of the first conductivity type) 1 containing silicon carbide and at a front surface thereof, further has an n⁻-type drift region (first semiconductor layer of the first conductivity type) 2 containing silicon carbide, and a p-type base region 5 containing silicon carbide, provided at a first surface of the n⁻-type drift region 2, opposite to a second surface thereof facing the n⁺-type silicon carbide substrate 1. The n⁺-type silicon carbide substrate 1 functions as a drain region. Further, between the n⁻-type drift region 2 and the n⁺-type silicon carbide substrate 1, for example, a buffer layer or the like that reduces the growth of crystal defects from the n⁺-type silicon carbide substrate 1 may be provided.

The n⁺-type silicon carbide substrate 1 is a silicon carbide single crystal substrate. The n⁻-type drift region 2 has a dopant concentration that is lower than that of the n⁺-type silicon carbide substrate 1. The n⁻-type drift region 2 reaches the p-type base region 5, is in contact with the p-type base region 5 and later-described p⁺-type regions 4, 26, and in a direction parallel to the front surface of the semiconductor substrate, reaches later-described trenches 25 and is in contact with gate insulating films 11. The dopant concentration of the n-type drift region 2 is, for example, not more than 5×10¹⁶ cm⁻³ and a thickness of the n-type drift region 2 is not less than 5.0 μm.

Further, between the n-type drift region 2 and the p-type base region 5, n-type high-concentration regions (not depicted) may be provided. In an instance in which n-type high-concentration regions are provided, at the later-described p⁺-type regions 4, 26 adjacent thereto, the n-type high-concentration regions are in contact with these regions and extend in a direction parallel to the front surface of the semiconductor substrate, reaching the trenches 25 and being in contact with the gate insulating films 11. The n-type high-concentration regions each have an upper surface in contact with the p-type base region 5 and a lower surface in contact with the n-type drift region 2. The n-type high-concentration regions have a dopant concentration that is lower than that of the n⁺-type silicon carbide substrate 1 and higher than that of the n⁻-type drift region 2.

At a second main surface (back surface, that is, a back surface of the silicon carbide substrate) of the n⁺-type silicon carbide substrate 1, a drain electrode 17 constituting a back electrode is provided. At a surface of the drain electrode 17, a drain electrode pad (not depicted) is provided.

In the silicon carbide substrate, at a first main surface (surface of side having the p-type base region 5) thereof, a trench structure is formed. More specifically, the trenches 25 penetrate through the p-type base region 5 from a first surface of the p-type base region 5, opposite to a second surface thereof facing the n⁺-type silicon carbide substrate 1 (first side of the silicon carbide substrate) and reach the n-type drift region 2 (in an instance in which the n-type high-concentration regions are provided, the n-type high-concentration regions).

Along inner walls of the trenches 25, the gate insulating films 11 are formed at bottoms and sidewalls of the trenches 25 and a gate electrodes 13 are formed on the gate insulating films 11 in the trenches 25. The gate insulating films 11 insulate the gate electrodes 13 from the n⁻-type drift region 2 and the p-type base region 5. A portion of each of the gate electrodes 13 may protrude from a top (side facing later-described source electrode 16) of each of the trenches 25, in a direction toward the source electrode 16.

In the n⁻-type drift region 2, at the first surface thereof (surface facing the silicon carbide substrate), opposite to the second surface thereof facing the n⁺-type silicon carbide substrate 1, upper p⁺-type partial regions (first semiconductor regions of the second conductivity type) 4a are provided. The upper p⁺-type partial regions 4a are provided, for example, between the trenches 25. Further, in the n-type drift region 2, lower p⁺-type partial regions 4b in contact with bottoms of the upper p⁺-type partial regions 4a, respectively, are provided. Further, at the bottoms of the trenches 25, the p⁺-type regions 26 are provided. The p⁺-type regions 26 in contact with the bottoms of the trenches 25 are provided at positions facing the bottoms of the trenches 25 in a depth direction (direction from the source electrode 16 to the back electrode), respectively. Between any adjacent two of the trenches 25, one of the upper p⁺-type partial regions 4a and one of the lower p⁺-type partial regions 4b constitutes a p⁺-type region 4.

Each of the p⁺-type regions 26 has a width that is equal to or greater than a width of each of the trenches 25. Further, each of the lower p⁺-type partial regions 4b has a width that is equal to or greater than a width of each of the upper p⁺-type partial regions 4a. The bottoms of the trenches 25 may reach the p⁺-type regions 26 or may be at positions in the n⁻-type drift region 2, between the p-type base region 5 and the p⁺-type regions 26.

In the p-type base region 5, at the first surface thereof, n⁺⁺-type source regions 7 and p⁺⁺-type contact regions 6 are selectively provided. Further, the n⁺⁺-type source regions 7 and the p⁺⁺-type contact regions 6 are in contact with each other.

Further, as depicted in FIG. 2, the lower p⁺-type partial regions 4b, the upper p⁺-type partial regions 4a, and the p⁺⁺-type contact regions 6 extend to ends of the active region 50. At the ends of the active region 50, preferably, ends of the lower p⁺-type partial regions 4b may be farther from the ends of the active region 50 that are the ends of the upper p⁺-type partial regions 4a and the p⁺⁺-type contact regions 6 by 3.0 μm or more.

An interlayer insulating film 14 is provided in an entire area at the first side of silicon carbide substrate so as to cover the gate electrodes 13 embedded in the trenches 25. The source electrode 16 is in contact with the n⁺⁺-type source regions 7 and the p⁺⁺-type contact regions 6, via contact holes opened in the interlayer insulating film 14. The source electrode 16 is electrically insulated from the gate electrodes 13 by the interlayer insulating film 14. On the source electrode 16, a source electrode pad (not depicted) is provided. Between the source electrode 16 and the interlayer insulating film 14, for example, a barrier metal 15 that prevents diffusion of metal atoms from the source electrode 16 to the gate electrodes 13 may be provided. A polyimide (not depicted) that functions as a protective film is provided at the surface of the silicon carbide semiconductor device 70. In FIG. 1, while only 2 MOS gate (metal-oxide-semiconductor insulated gate) structures are depicted in the active region 50, further MOS gate structures may be disposed in parallel.

In the edge termination region 60 as well, the n⁻-type drift region 2 described above is provided at the front surface of the n⁺-type silicon carbide substrate 1.

Further, in the edge termination region 60, a FLR structure (second semiconductor region of the second conductivity type) 30 is provided. Further, an n⁺⁺-type (p⁺⁺-type) channel stopper region (not depicted) functioning as a channel stopper is provided at the surface of the n⁻-type drift region 2, outside the FLR structure 30 (closer to a chip end that is the FLR structure 30). High breakdown voltage in a lateral direction is maintained by pn junctions between the FLR structure 30 and the n⁻-type drift region 2. The edge termination region 60 is covered by a field oxide film (not depicted) and on the field oxide film, a HTO film (not depicted) and an interlayer insulating film (not depicted) are sequentially deposited.

In the silicon carbide semiconductor device according to the embodiment, in the FLR structure 30, in the silicon carbide substrate, at the first main surface thereof, multiple p-type FLRs (first sub-regions of the second conductivity type) 31 are disposed. High-concentration p-type FLR regions 32 that are shallow regions with a high concentration are provided respectively in the FLRs 31, in a center portion at the surface thereof. In each of the FLRs 31, at the surface thereof, a region that is between the FLR 31 and opposite side surfaces of the high-concentration p-type FLR region 32 and that is closer to the n⁺-type silicon carbide substrate 1 than is the high-concentration p-type FLR region 32 is a low-concentration p-type FLR region 33 having a dopant concentration that is lower than that of the high-concentration p-type FLR regions 32. The high-concentration p-type FLR regions 32 may have a same depth and a same dopant concentration as the p⁺⁺-type contact regions 6. The dopant concentration of the high-concentration p-type FLR regions 32 is, for example, in a range of 5×10¹⁹ cm⁻³ to 2×10²⁰ cm⁻³. The depth of a lower surface of each of the low-concentration p-type FLR regions 33 may be equal to a depth of a lower surface of each of the upper p⁺-type partial regions 4a. The dopant concentration of the low-concentration p-type FLR regions 33 may be a same dopant concentration as that of the upper p⁺-type partial regions 4a.

In each of the FLRs 31, preferably, a width between the side surface of the FLR 31 and the side surface of the high-concentration p-type FLR region 32 may be less than a width of each of the high-concentration p-type FLR regions 32. More preferably, to suppress the electric field strength at pn junctions near the high-concentration p-type FLR regions 32, the width may be 3% or more of the width (at the uppermost surface of the n⁻-type drift region 2) of an innermost one of the FLRs 31 closest to the active region 50 and to suppress fluctuations in the breakdown voltage due to surface charges, the width may be 20% or less thereof.

The depth of the lower surfaces of the FLRs 31 and a depth of a lower surface of a region combining the upper p⁺-type partial regions 4a and the p⁺⁺-type contact regions 6 are shallower than the lower surfaces of the lower p⁺⁺-type partial regions 4b. In a direction from the active region 50 to the chip end, the FLRs 31 are disposed in descending order of width at intervals that progressively increase. For example, as depicted in FIG. 2, when 14 of the FLRs 31 (F1 to F14) are disposed, respective widths of the FLRs 31, the widths (distances) between the FLRs 31 (W2 to W14), and a width (distance) W1 between the innermost one of the FLRs 31 (F1) and an outermost one of the p⁺⁺-type contact regions 6 are as depicted in Table 1 below.

TABLE 1

| | W1 | W2 | W3 | W4 | W5 | W6 | W7 | W8 | W9 | W10 | W11 | W12 | W13 | W14 |
|---|---|---|---|---|---|---|---|---|---|---|---|---|---|---|
| INTERVAL [μm] | 1.0 | 1.1 | 1.2 | 1.25 | 1.35 | 1.5 | 1.65 | 1.8 | 2.0 | 2.25 | 2.55 | 2.9 | 3.3 | 3.75 |
| | F1 | F2 | F3 | F4 | F5 | F6 | F7 | F8 | F9 | F10 | F11 | F12 | F13 | F14 |
| WIDTH [μm] | 7.0 | 7.0 | 6.0 | 5.0 | 4.0 | 3.0 | 2.0 | 2.0 | 1.0 | 1.0 | 1.0 | 1.0 | 1.0 | 1.0 |

As depicted in Table 1, at the uppermost surface of the n⁻-type drift region 2, the respective widths of the FLRs 31 closest to the active region 50 are 6.0 μm or greater and the respective widths of the FLRs 31 closest to the chip end are 2.0 μm or less; the width of any one of the FLRs 31 being equal to or less than the width of an adjacent one of the FLRs 31 closer to the active region 50; and at the uppermost surface of the n⁻-type drift region 2, the intervals between the FLRs 31 are 2.0 μm or more closest to the active region 50 and 3.0 μm or less closest to the chip end. Further, an interval between any one of the FLRs 31 and an adjacent one of the FLRs 31 closer to the active region 50 is equal to or greater than an interval between the any one of the FLRs 31 and an adjacent one of the FLRs 31 closer to the FLRs 31 and preferably, 10 or more of the FLRs 31 may be provided.

In the embodiment, from the end of the p⁺⁺-type contact regions 6 of the active region 50 to a predetermined number (for example, 8) of the FLRs 31 from the active region 50, a low-concentration inter-FLR layer (third semiconductor region of the second conductivity type) 34 having a concentration lower than that of the low-concentration p-type FLR regions 33 and shallower than the low-concentration p-type FLR regions 33 is provided. The low-concentration inter-FLR layer 34 is provided in a region deeper than is the first main surface of the silicon carbide substrate and, for example, a front surface (surface opposite to that facing the n⁺-type silicon carbide substrate 1) of the low-concentration inter-FLR layer 34 is closer to the first main surface of the silicon carbide substrate than is a lower surface of each of the high-concentration p-type FLR regions 32. Further, a lower surface (surface facing the n⁺-type silicon carbide substrate 1) of the low-concentration inter-FLR layer 34 is between the lower surface of each of the high-concentration p-type FLR regions 32 and the lower surface of each of the low-concentration p-type FLR regions 33.

Further, between the first main surface of the semiconductor substrate and the front surface of the low-concentration inter-FLR layer 34, n⁻-type regions 35 (the n⁻-type drift region 2, fourth semiconductor regions of the second conductivity type) are provided. Preferably, a thickness of each of the n⁻-type regions 35 may be equal to or less than a distance between the lower surface of the low-concentration inter-FLR layer 34 and the lower surface of each of the FLRs 31 and from the perspective of suppressing the electric field strength at the pn junctions between the FLRs 31 and the n⁻-type drift region 2, preferably may be smaller than the thickness of each of the high-concentration p-type FLR regions 32.

Further, as depicted in FIG. 1, preferably, an end of the low-concentration inter-FLR layer 34 facing the active region 50 may be connected to ends of the p⁺⁺-type contact regions 6 or the upper p⁺-type partial regions 4a, and an end of the low-concentration inter-FLR layer 34 facing the chip end may be located closer to the chip end than is a portion where a first interval of the FLRs 31 from the active region 50 is at least 1.5 μm or the width of the FLRs 31 is 3.0 μm or less, and the end of the low-concentration inter-FLR layer 34 facing the chip end may be connected to the FLRs 31.

Here, in an edge termination structure 60 that uses the FLRs 31, which are shallower than the lower p⁺-type partial regions 4b, the electric field is dispersed to a maximal extent in the FLR structure 30 and then, dielectric breakdown occurs at the ends of the lower p⁺-type partial regions 4b, thereby ensuring the breakdown voltage. However, when positive charge accumulates at the surface of the edge termination structure 60, the electric field of the FLRs 31 and/or the ends of the upper p⁺-type partial regions 4a increases, whereby dielectric breakdown occurs by a lower voltage. While the electric field is relaxed by reducing the intervals between the ends of the upper p⁺-type partial regions 4a and between the FLRs 31, even when the intervals are reduced as much as possible within the limits of processing, a problem arises in that with consideration of spreading due to process variation, a necessary breakdown voltage may not be ensured.

In the embodiment, when the low-concentration inter-FLR layer 34, which is shallow and has a low concentration, is provided between the FLRs 31, during operation of the device, the low-concentration inter-FLR layer 34 is depleted and the side surfaces of the FLRs 31 become connected by the depleted p-type region. As a result, even when the area of the pn junctions of the high-concentration p-type regions where electric field tends to concentrate decreases and the interval spreads due to process variation, dispersion of the electric field to the FLRs 31 relatively closer to the chip end is facilitated. Thus, the low-concentration inter-FLR layer 34 is provided in a form that connects the FLRs 31, whereby sufficient surface charge tolerance is ensured even when dimensions of each of the FLRs 31 of the FLR structure 30 vary, thereby enabling stabilization of the edge breakdown voltage. Furthermore, the breakdown voltage may be stably ensured even without performing SiC etching and high-acceleration ion implantation of the edge termination region 60, and since neither SiC etching or high-acceleration ion implantation is used, manufacturing costs may be reduced.

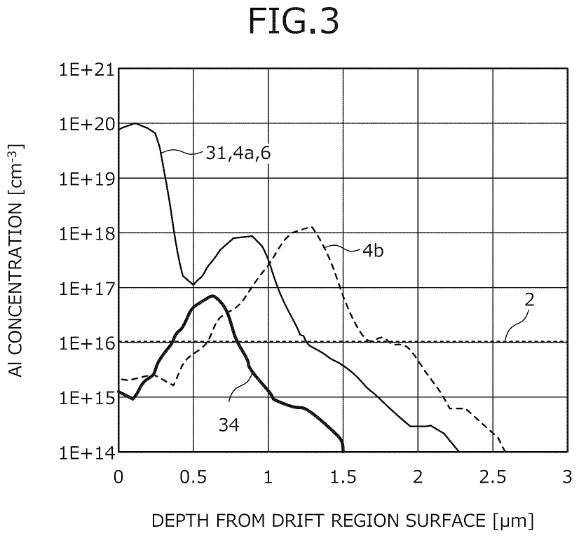

FIG. 3 is a graph depicting concentration distribution in the depth direction of the p-type layer of the silicon carbide semiconductor device according to the embodiment. In FIG. 3, a vertical axis indicates the concentration of the dopant (e.g., aluminum (Al)) of the p-type layer, in units of cm⁻³. A horizontal axis indicates the depth from the surface of the n⁻-type drift region 2 in units of μm. In FIG. 3, for example, 1×10¹⁶ cm⁻³ is depicted as the dopant concentration of the n⁻-type drift region 2.

In FIG. 3, in the center portion of each of the FLRs 31, the dopant concentration of a region that is a combination of one of the high-concentration p-type FLR regions 32 and one of the low-concentration p-type FLR regions 33, and a region that is a combination of one of the upper p⁺-type partial regions 4a and one of the p⁺⁺-type contact regions 6 is indicated by a thin line. In a region from the surface of the n-type drift region 2 to a depth of 0.5 μm, a maximum value is in a range of 5×10¹⁹ cm⁻³ to 2×10²⁰ cm⁻³. Further, in these regions, in a region of a depth 0.5 μm or more to not more than 1.0 μm, a maximum value is in a range of 5×10¹⁷ cm⁻³ to 2×10¹⁸ cm⁻³. Further, in these regions, in a region of a depth 1.0 μm or more, the dopant concentration monotonically decreases and at a depth 1.0 μm to 1.5 μm, the dopant concentration is the same as that of the n⁻-type drift region 2. Further, the high-concentration p-type FLR regions 32 may have a dopant concentration in a range of, for example, 5×10¹⁹ cm⁻³ to 2×10²⁰ cm⁻³ and the low-concentration p-type FLR regions 33 may have a dopant concentration that is 5×10¹⁹ cm⁻³ or less and higher than that of the n⁻-type drift region 2.

Further, as depicted in FIG. 3, the dopant concentration (thick line in FIG. 3) of the low-concentration inter-FLR layer 34 exhibits a maximum value only in a region from the surface of the n⁻-type drift region 2 to a depth 1.0 μm and in a region deeper than the depth where the dopant concentration of the high-concentration p-type FLR regions 32 is highest; the maximum value is 2×10¹⁷ cm⁻³ or less and higher than the dopant concentration of the n-type drift region 2. Further, the dopant concentration of the low-concentration inter-FLR layer 34, at a depth in a range from 0.5 μm to 1.0 μm, is lower than the dopant concentration of the FLRs 31, in a region deeper than a position where the dopant concentration of the FLRs 31 is highest.

Further, as depicted in FIG. 3, the dopant concentration (dotted line in FIG. 3) of the lower p⁺-type partial regions 4b exhibits a maximum value in a region of a depth 1.0 μm or more, and the maximum value of the dopant concentration of the lower p⁺-type partial regions 4b is higher than the maximum value of the dopant concentration of the FLRs 31 at a depth in a range of 0.5 μm to 1.0 μm. Further, in a region from a position where the dopant concentration of the FLRs 31, which are in a region of a depth 0.5 μm from the surface of the n⁻-type drift region 2, exhibits a maximum value, to a position where the dopant concentration of the lower p⁺-type partial regions 4b exhibits a maximum value, the combined dopant concentration of the upper p⁺-type partial regions 4a, the p⁺⁺-type contact regions 6, and the lower p⁺-type partial regions 4b is normally higher than the dopant concentration of the n⁻-type drift region 2.

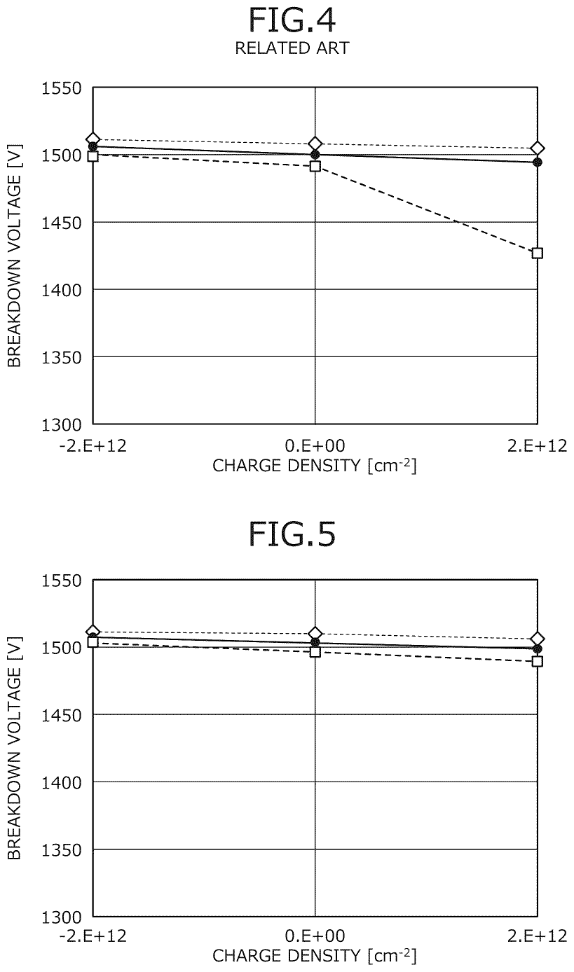

FIG. 4 is a graph depicting change of the edge breakdown voltage due to edge surface charge and variation of FLR dimensions of a conventional silicon carbide semiconductor device. FIG. 5 is a graph depicting change of the edge breakdown voltage due to edge surface charge and variation of FLR dimensions of the silicon carbide semiconductor device according to the embodiment. In FIGS. 4 and 5, a vertical axis indicates breakdown voltage in units of V. A horizontal axis indicates charge density at the surface of the n⁻-type drift region 2 in units of cm⁻².

FIGS. 4 and 5 depict simulation results for an instance in which the FLR widths and the FLR intervals are formed according to the dimensions in Table 1 (curve with solid line connecting ●), an instance in which the FLR widths are 0.3 μm wider and the FLR intervals are 0.3 μm are narrower (curve with dotted line connecting ⋄), and an instance in which the FLR width is 0.3 μm narrower and the FLR intervals are 0.3 μm wider (curve with dashed line connecting □).

In only the conventional FLR structure 30, when the FLR widths are 0.3 μm narrower and the FLR intervals are 0.3 μm wider due to process variation, the breakdown voltage greatly decreases when charge of +2E+12 cm⁻² is applied to the edge surface. On the other hand, in the embodiment in which the low-concentration inter-FLR layer 34 is provided, even when both process variation and edge surface charge are at a maximum, the breakdown voltage remains almost unchanged.

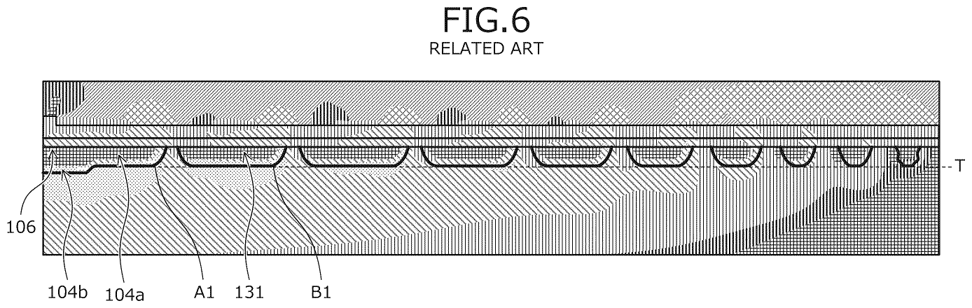

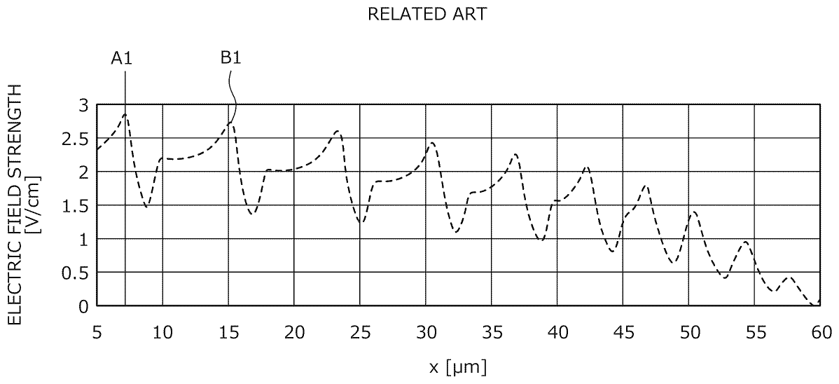

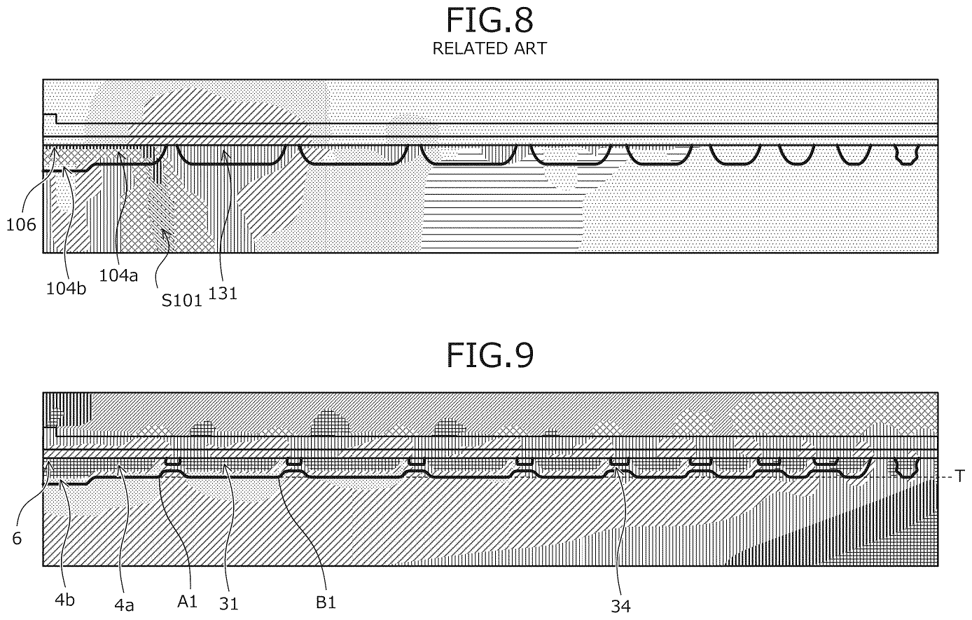

In the conventional silicon carbide semiconductor device, in the case in which the FLR widths are 0.3 μm narrower and the FLR intervals are 0.3 μm wider, indicated by the curve with the dashed line connecting in FIG. 4, electric field distribution and the location of dielectric breakdown are as follows. FIG. 6 is a cross-sectional view depicting electric field distribution of the conventional silicon carbide semiconductor device. FIG. 7 is a graph depicting the electric field distribution of the conventional silicon carbide semiconductor device. FIG. 8 is a cross-sectional view depicting the location of dielectric breakdown of the conventional silicon carbide semiconductor device. FIG. 7 depicts the electric field distribution at the bottom (dotted line T in FIG. 6) of the FLRs. A vertical axis indicates the electric field strength in units of MV/cm. A horizontal axis indicates distance from lower p⁺-type partial regions 104b in units of μm. In FIG. 7, A1 indicates the electric field strength of ends of upper p⁺-type partial regions 104a and B1 indicates the electric field strength at the bottom of FLR 131 closest to the active region.

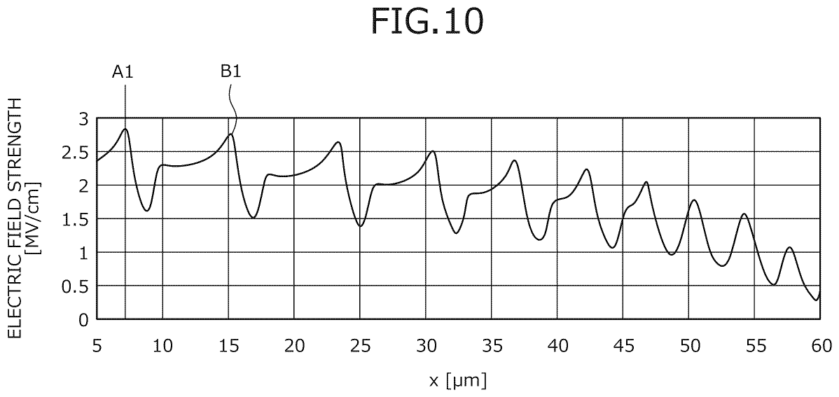

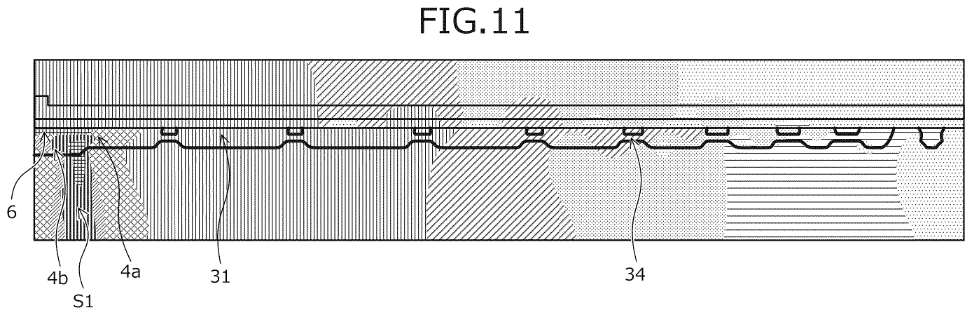

Further, in the silicon carbide semiconductor device according to the embodiment, in the case in which the FLR widths are 0.3 μm narrower and the FLR intervals are 0.3 μm wider, indicated by the curve with the dashed connecting u in FIG. 5, the electric field distribution and the location of dielectric breakdown are as follows. FIG. 9 is a cross-sectional view depicting the electric field distribution of the silicon carbide semiconductor device according to the embodiment. FIG. 10 is a graph depicting the electric field distribution of the silicon carbide semiconductor device according to the embodiment. FIG. 11 is a cross-sectional view depicting the location of dielectric breakdown of the silicon carbide semiconductor device according to the embodiment. FIG. 10 depicts the electric field distribution at the bottom (dotted line T in FIG. 9) of the FLRs. A vertical axis indicates the electric field strength in units of MV/cm. A horizontal axis indicates distance from the lower p⁺-type partial regions 4b in units of μm. In FIG. 10, A1 indicates the electric field strength at the ends of the upper p⁺-type partial regions 4a and B1 indicates the electric field strength at the bottom of the FLR 31 closest to the active region 50.

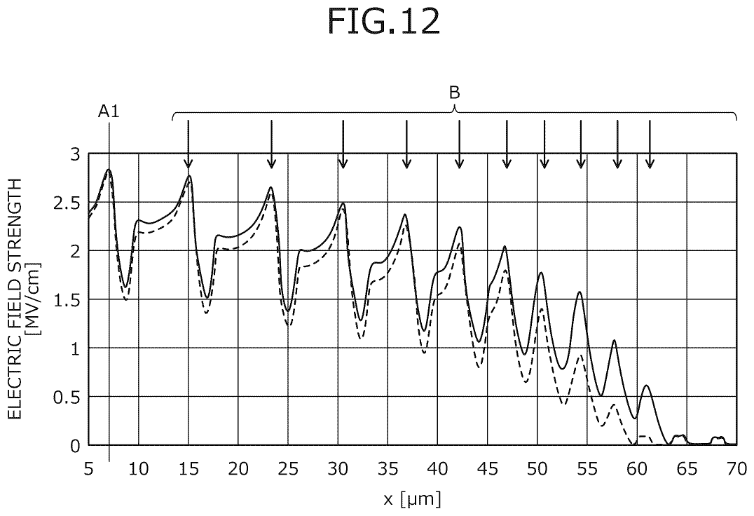

FIG. 12 is a graph depicting the electric field distribution of the conventional silicon carbide semiconductor device and the silicon carbide semiconductor device according to the embodiment. FIG. 12 is a combination of FIGS. 7 and 10. In FIG. 12, A1 indicates the electric field strength of the ends of the upper p⁺-type partial regions 4a, 104a of the active region 50 and B indicates the electric field strength at the bottom of the FLRs 31, 131. The present embodiment is indicated by a solid line, and the conventional device is indicated by a dotted line. As depicted in FIG. 12, the embodiment in which the low-concentration inter-FLR layer 34 is used may disperse electric field to the chip end more than the conventional device and thus, the concentration of electric field at the ends of the upper p⁺-type partial regions 4a of the active region 50 and corner portions of the FLRs 31 is relaxed. Thus, conventionally, as depicted in FIG. 8, while the location of dielectric breakdown is at ends S101 of p⁺⁺-type contact regions 106 of the active region, in the present embodiment, as depicted in FIG. 11, the location of dielectric breakdown is at ends S1 of the lower p⁺-type partial regions 4b of the active region 50. As a result, the silicon carbide semiconductor device according to the embodiment may prevent decreases in the breakdown voltage even under strictest conditions for surface charge and variation of dimensions.

Further, in a method of manufacturing the semiconductor device according to the embodiment, for example, in the n-type drift region 2, the FLR structure 30 of the edge termination region 60 may be formed by ion implantation with the same conditions as the conditions of the ion implantation for forming the p-type regions (the upper p⁺-type partial regions 4a) for electrically connecting the p-type regions (the lower p⁺-type partial regions 4b) below the trenches 25 and the source electrode 16 of the active region 50. Further, the low-concentration inter-FLR layer 34 may be formed in the n⁻-type drift region 2 by ion implantation. Other structures may be fabricated similarly to an instance of, for example, a MOSFET of a 1200V breakdown voltage class.

As described above, according to the embodiment, the low-concentration inter-FLR layer is provided in a form that connects the FLRs, whereby sufficient surface charge tolerance is ensured even when dimensions of each of the FLRs 31 of the FLR structure 30 vary, thereby enabling stabilization of the edge breakdown voltage. Furthermore, even without performing SiC etching and high-acceleration ion implantation of the edge termination region, the breakdown voltage may be stably ensured and since neither SiC etching or high-acceleration ion implantation is used, manufacturing costs may be reduced.

In the foregoing, in the present disclosure, various modifications within a range not departing from the spirit of the disclosure and in the described embodiment, for example, dimensions and dopant concentrations of regions, etc. may be variously set according to necessary specifications. Further, in the described embodiment, while an instance in which silicon carbide is used as a wide band gap semiconductor, a wide band gap semiconductor other than silicon carbide, for example, gallium nitride (GaN) or the like is also applicable. Further, in the embodiments, while the first conductivity type is assumed to be an n-type and the second conductivity type is assumed to be a p-type, the present disclosure is similarly implemented when the first conductivity type is a p-type and the second conductivity type is an n-type.

According to the described disclosure, the low-concentration inter-FLR layer (third semiconductor region of the second conductivity type) is provided in a form that connects the FLRs (first sub-regions of the second conductivity type), whereby sufficient surface charge tolerance is ensured even when dimensions of each of the FLRs of the FLR structure vary, thereby enabling stabilization of the edge breakdown voltage. Furthermore, the breakdown voltage may be stably ensured even without performing SiC etching and high-acceleration ion implantation of the edge termination region, and since neither SiC etching or high-acceleration ion implantation is used, manufacturing costs may be reduced.

The semiconductor device according to the present disclosure achieves an effect in that in a FLR structure, variation of the breakdown voltage due to variations in dimensions and edge surface charge may be reduced.

As described, the semiconductor device according to the present disclosure is useful for power semiconductor devices used in power converting equipment of inverters, etc., power source devices of various industrial machines, etc., and igniters of automobiles.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, having an active region through which a main current flows and a termination region surrounding a periphery of the active region, in a plan view;
a first semiconductor layer of the first conductivity type, provided on the semiconductor substrate in the active region and the termination region, the first semiconductor layer having a dopant concentration lower than a dopant concentration of the semiconductor substrate, the first semiconductor layer having a first surface and a second surface opposite to each other, the second surface facing the semiconductor substrate;
a plurality of first semiconductor regions of a second conductivity type, provided in the first semiconductor layer, at the first surface thereof in the active region;
a second semiconductor region of the second conductivity type, provided in the termination region, the second semiconductor region having a plurality of first sub-regions of the second conductivity type, provided at intervals at the first surface of the first semiconductor layer, each of the plurality of first sub-regions having a first surface and a second surface opposite of each other, the second surface facing the semiconductor substrate;
a third semiconductor region of the second conductivity type, provided in the first semiconductor layer in the termination region, between a predetermined number of the plurality of first sub-regions from an end of the plurality of first semiconductor regions, the third semiconductor region having a concentration lower than that of the plurality of first sub-regions, the third semiconductor region having a first surface and a second surface opposite to each other, the second surface facing the semiconductor substrate and being provided closer to the first surface of the first semiconductor layer than is the first surface of each of the plurality of first sub-regions; and
a plurality of fourth semiconductor regions of the first conductivity type, provided in the first semiconductor layer in the termination region, between the first surface of the first semiconductor layer and the third semiconductor region, wherein
the predetermined number of the plurality of first sub-regions are connected by the third semiconductor region and the plurality of fourth semiconductor regions.

2. The semiconductor device according to claim 1, wherein
each of the plurality of first sub-regions has:
a center region having
a second sub-region at the first surface of the first semiconductor layer, and
a third sub-region at a side of the second sub-region facing the semiconductor substrate, the second sub-region having a higher dopant concentration than the third sub-region,
an inner-side region provided closer to the active region than is the center region, and
an outer-side region provided opposite to the inner-side region with the center region intervening therebetween; and
each of the inner-side region and the outer-side region has a dopant concentration that is lower than that of the second sub-region.

3. The semiconductor device according to claim 1, wherein
the plurality of fourth semiconductor regions is located between the first surface of the first semiconductor layer and the first surface of the third semiconductor region, and
each of the plurality of fourth semiconductor regions has a thickness not more than a distance from the second surface of the third semiconductor region to the second surface of the each of the plurality of first sub-regions.

4. The semiconductor device according to claim 2, wherein
the plurality of fourth semiconductor regions is located between the first surface of the first semiconductor layer and the first surface of the third semiconductor region, and
each of the plurality of fourth semiconductor regions has a thickness that is less than a thickness of the second sub-region of each of the plurality of first sub-regions.

5. The semiconductor device according to claim 2, wherein
in each of the plurality of first sub-regions:
the dopant concentration of the second sub-region is in a range of 5×10¹⁹ cm⁻³ to 2×10²⁰ cm⁻,
the dopant concentration of the third sub-region is in a range of 1×10¹⁶ cm⁻³ to 5×10¹⁹ cm⁻³, and
the dopant concentration of each of the inner-side region and outer-side region is in a range of 1×10¹⁶ cm⁻³ to 5×10¹⁹ cm⁻.

6. The semiconductor device according to claim 2, wherein in each of the plurality of first sub-regions, in a direction parallel to the first surface of the first semiconductor layer, a width of the center region is wider than each of a width of the inner-side region and a width of the outer-side region.

7. The semiconductor device according to claim 2, wherein in each of the plurality of first sub-regions, in a direction parallel to the first surface of the first semiconductor layer, a width of the inner-side region and a width of the outer-side region are each in a range of 3% to 20% of a width of an innermost one of the plurality of first sub-regions provided closest to the active region.

8. The semiconductor device according to claim 1, wherein the first surface of the first semiconductor region and the first surface of the second semiconductor region are a same surface as the first surface of the first semiconductor layer.

9. The semiconductor device according to claim 1, wherein
in a width direction parallel to the first surface of the first semiconductor layer, the plurality of first sub-regions has a plurality of widths
the plurality of first sub-regions includes:
an innermost first sub-region, which is closest to the active region and has a width of 6.0 μm or greater at the first surface of the first semiconductor layer, and
an outermost first sub-region, which is farthest from the active region and has a width of 2.0 μm at the first surface of the first semiconductor layer,
the width of each of the plurality of first sub-regions being equal to or less than the width of one of the plurality of first sub-regions adjacent thereto and closer to the active region,
at the first surface of the first semiconductor layer, the intervals between the plurality of first sub-regions includes:
an innermost interval that closest to the active region, and is 2.0 μm or less, and
an outermost interval that is farthest from the active region, is 3.0 μm or less,
each of the intervals between the plurality of first sub-regions being greater than one of the plurality of intervals adjacent thereto and closer to the active region, and
the plurality of first sub-regions includes ten or more first sub-regions.

10. The semiconductor device according to claim 1, wherein
a dopant concentration of the third semiconductor region exhibits a maximum value thereof closer to the semiconductor substrate than to the first surface of the first semiconductor layer, the maximum value being 2×10¹⁷ cm⁻³ or less and higher than the dopant concentration of the first semiconductor layer, and
the dopant concentration of the third semiconductor region, in a region deeper than a depth where a dopant concentration of the plurality of first sub-regions exhibits a maximum value thereof, is lower than the dopant concentration of the plurality of first sub-regions.

11. The semiconductor device according to claim 1, wherein
in a width direction parallel to the first surface of the first semiconductor layer, the plurality of first sub-regions has a plurality of widths,
the semiconductor device has a region in which one of the intervals between the plurality of first sub-regions closest to the active region is 1.5 μm or more, or a width of one of the plurality of first sub-regions is 3.0 μm or less, and
the third semiconductor region has a first end and a second end opposite to each other, the first end facing the active region, and the second end being farther from the active region than is said region.
